(19) United States
(12) Patent Application Publication
(10) Pub. No.: US 2011/0094074 A1
(43) Pub. Date: Apr. 28, 2011

(54) Pick-and-place device for ICs

(76) Inventors: Ming-Chih Lo, Yonghe City (TW); Chen-Nan Ku, Shin-Dian (TW)

(21) Appl. No.: 12/654,320

(22) Filed: Dec. 17, 2009

(30) Foreign Application Priority Data
Oct. 28, 2009 (CN) 2009 10206677.X

(51) Int. Cl. H01L 21/64

(52) U.S. Cl. 29/25.01

(57) ABSTRACT

A pick-and-place device for ICs according to the present invention comprises a base, a plurality of rotational structures, a plurality of pick-and-place structures, a transmission structure, and a driving structure. The pick-and-place structures are mounted on the base, and individually have one nozzle. The nozzles can move up-and-down respectively. The rotational structures are mounted on the base, and drive the nozzles to rotate. The transmission structure is assembled with the rotational structures, and drives the rotational structures to rotate. The driving structure is mounted on the base. The driving structure drives the transmission structure. The transmission structure further drives the rotational structures to rotate so that the nozzles are rotated. The nozzles are rotated driven by the rotational structures, ICs can be rotated following up the rotation of the nozzles during the pick-and-place process. Therefore, an advantage of the present invention is to enhance the convenience during the pick-and-place process.

### BACKGROUND OF THE INVENTION

1. Field of the Invention

The present invention relates to a pick-and-place device, and more particularly, to a pick-and-place device for integrated circuits (ICs).

2. Description of Related Art

With the vast improvement in technology, various types of electronic products have been widely accepted by consumers. Therefore, the demand for ICs used to electronic products grows significantly. Before ICs are embedded in the electronic products, it requires burning. In the burning process, the ICs are put into the burning machine. The pre-defined program is burned into the ICs. So, the ICs can have a capability to control the functions of other components in the electronic products. In order to reduce the operational time of burning for the ICs, recently the burning of the ICs often uses an automatic chip burning machine for accomplishment. Therefore, the overall burning time of ICs can be reduced, and the production speed of ICs can be further enhanced.

In the burning process, the ICs are put to the burning machine from the material staging area by a pick-and-place device. After the ICs are completely burned, the pick-and-place device will put the finished ICs to the next work station. For example, the ICs after burning are put into the chip slot of electronic products or put into the chip slot of the testing units of ICs by the pick-and-place device. There is a limitation of direction for the ICs to be put into the chip slot. So, in the process of picking or placing the ICs to the chip slot of burning machines, electronic products, or testing units, most situations require rotating the ICs for accurately putting the ICs into the chip slot. However, conventional pick-and-place devices for rotating the ICs have complicated structure and large volume. So, it is not easy to maintain the devices, and requires high cost to do so. Also, the efficiency of processing the ICs will be affected. Further, since large volume requires more space, it has certain limitations of placement.

The present invention is to provide a pick-and-place device for ICs. It has a simple structure, and can pick, place, or rotate multiple the ICs simultaneously or separately. Therefore, the present invention can enhance the convenience of picking-and-placing the ICs, and further enhance the efficiency of processing the ICs.

### SUMMARY OF THE INVENTION

One objective of the present invention is to provide a pick-and-place device for ICs which can rotate multiple ICs during the pick-and-place process. So, it can enhance the convenience of picking-and-placing the ICs.

Another objective of the present invention is to provide a pick-and-place device for ICs which has a simple structure and small volume. Therefore, it is easy to be maintained, requires minimum space to operate, and has lower operation cost.

The present invention is to provide a pick-and-place device for ICs which includes a base, a plurality of pick-and-place structures, a plurality of rotational structures, a transmission structure, and a driving structure. The pick-and-place structures are mounted on the base, and individually have one nozzle. Each nozzle can move up-and-down. The rotational structures are mounted on the base, and drive the nozzles to rotate. The transmission structure is assembled with the rotational structures, and drives the rotational structures to rotate. The driving structure is mounted on the base, and drives the transmission structure. The transmission structure further drives the rotational structures to rotate so that the nozzles are rotated. The nozzles are rotated driven by the rotational structures, ICs can be rotated following up the rotation of the nozzles during the pick-and-place process. Therefore, an advantage of the present invention is to enhance the convenience during the pick-and-place process.

### BRIEF DESCRIPTION OF THE DRAWINGS

FIG. 1A is a 3D view showing a pick-and-place device for ICs according to one embodiment of the present invention;

FIG. 1B is another 3D view showing the pick-and-place device for ICs according to one embodiment of the present invention;

FIG. 2 is a 3D view showing the hollow shaft, the rotational structure, the transmission structure, and the pick-and-place structure according to one embodiment of the present invention;

FIG. 3 is a schematic drawing showing the rotational structure according to one embodiment of the present invention;

FIG. 4A is a front view showing the linear sleeve assembled with the hollow shaft according to one embodiment of the present invention;

FIG. 4B is a top view showing the linear sleeve assembled with the hollow shaft according to one embodiment of the present invention;

FIG. 5 is a front view showing the pick-and-place device for ICs according to one embodiment of the present invention; and

FIG. 6 is a 3D view showing the pick-and-place device for ICs assembled with a moveable device according to one embodiment of the present invention.

### DESCRIPTION OF THE PREFERRED EMBODIMENTS

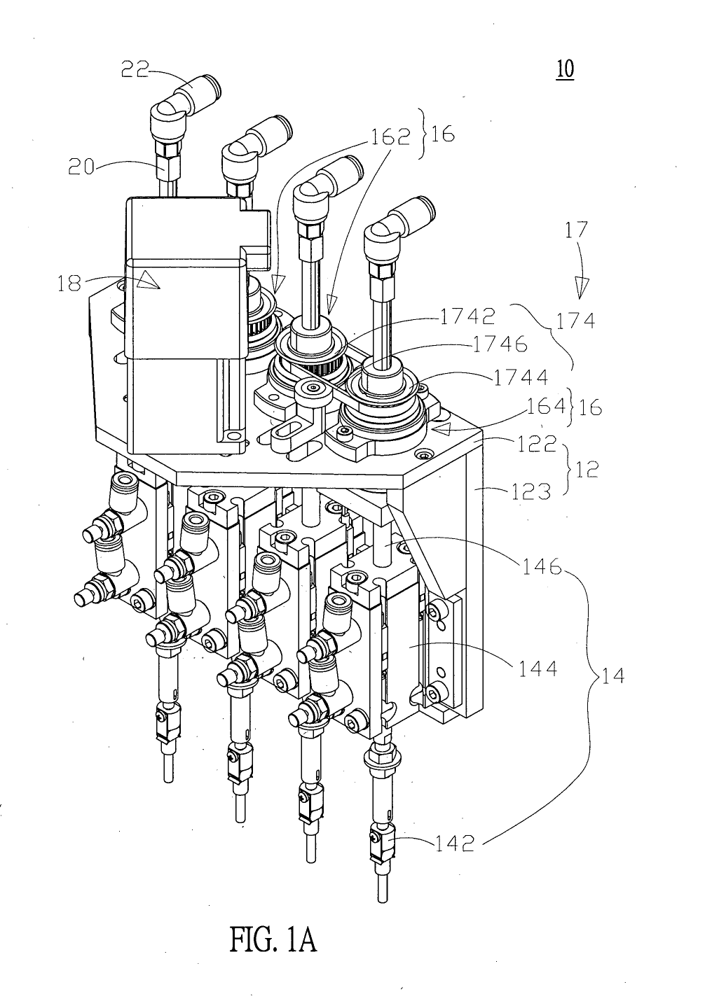

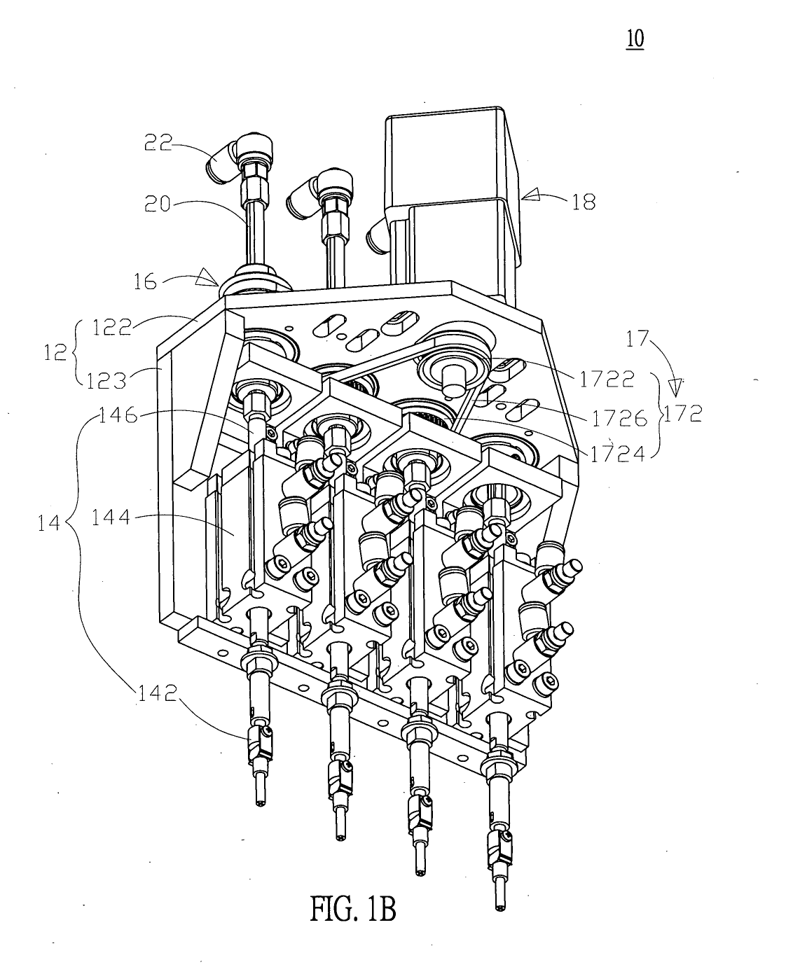

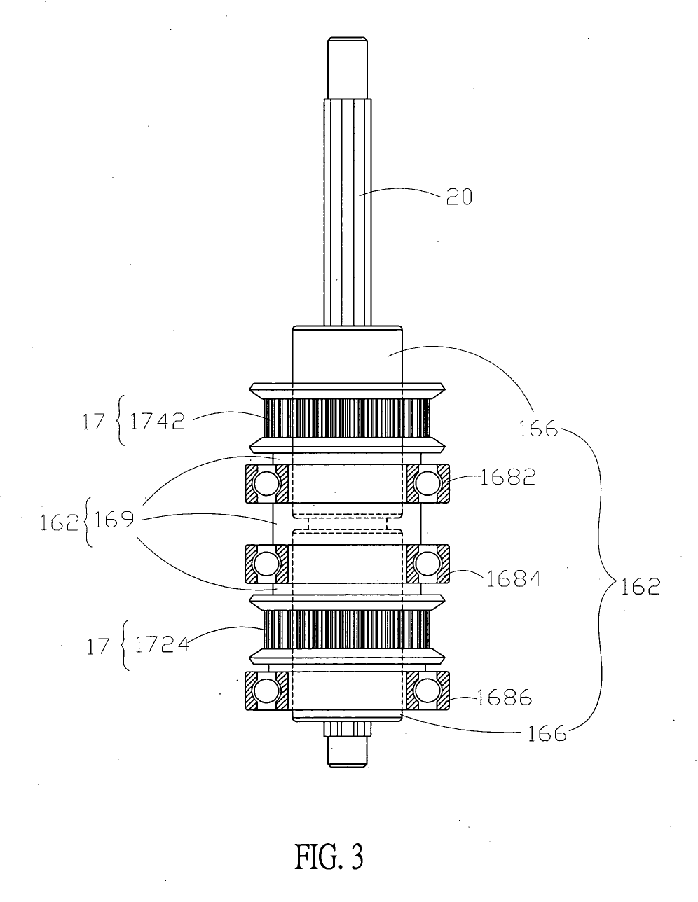

Referring to FIG. 1A and FIG. 1B, FIG. 1A and FIG. 1B are 3D view showing a pick-and-place device for ICs from different perspectives according to one embodiment of the present invention. As shown in the figures, a pick-and-place device 10 for ICs of the present invention includes a base 12, a plurality of pick-and-place structures 14, a plurality of rotational structures 16, a transmission structure 17, and a driving structure 18. The base (12) includes a base board 122 and a back board 123. The base board 122 is mounted on the top of the back board 123. The pick-and-place structures 14 are mounted on the back board 123 of the base 12. The pick-and-place structures 14 individually have one nozzle 144 for picking and placing ICs. The rotational structures 16 are mounted on the base board 122 of the base 12. The rotational structures 16 are used to drive the nozzles 142 to rotate. The detailed structure of the rotational structures 16 is shown in FIG. 3, and described afterward.

The transmission structure 17 is assembled with the rotational structures 16 and the driving structure 18. The transmission structure 17 is used to drive the rotational structures 16 to rotate. The driving structure 18 is mounted on the base board 122 of the base 12. The driving structure 18 is used to drive the transmission structure 17 for driving the rotational structures 16 to rotate. The rotational structures 16 further can drive the nozzles 142 to rotate. A positioning motor is one embodiment for the driving structure 18.

The nozzles 142 of the present invention are rotated by the driving structure 18 through the transmission structure 17 and the rotational structures 16. Therefore, the pick-and-place device 10 of the present invention has a simple structure and small volume. Thus, it is easy to be maintained, requires minimum space to operate, and has lower operation cost. Besides, the pick-and-place device 10 of the present invention can pick and place multiple ICs simultaneously. Also, it can rotate these ICs to the correct direction during the pick-and-place process in order to secure the ICs are located in the chip slot. Therefore, it can enhance the convenience of picking-and-placing ICs.

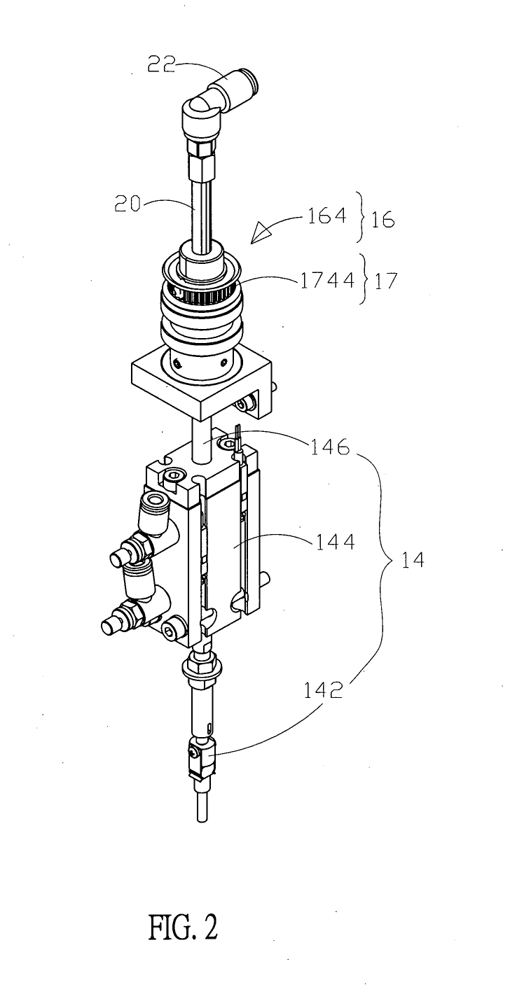

Please also refer to FIG. 2, the present invention further comprises a plurality of hollow shafts 20. Each hollow shaft 20 individually is passed through each rotational structure 16 and further connected to the nozzle 142. In order to conveniently make the hollow shafts 20 connect with an external vacuum device, the present invention further includes a plurality of connecting ports 22. The connecting ports 22 are individually connected with the top of the hollow shafts 20. A quick coupler is one embodiment for the connecting ports 22. Therefore, it is more convenient for users to connect the vacuum device with the hollow shafts 20. Each pick-and-place structure 14 of the present invention includes a nozzle 142, an actuator 144, and a transmission shaft 146. The actuator 144 is mounted on the back board 123 of the base 12. A pneumatic cylinder is one embodiment for the actuator 144. The transmission shaft 146 is passed through the actuator 144 and connected with the nozzle 142. The transmission shaft 146 is a hollow shaft. The transmission shaft 146 and the hollow shaft 20 are interlinked. The hollow shaft 20 is passed through the rotational structure 16 and connected with the transmission shaft 146. Accordingly, the hollow shaft 20 is connected with the nozzle 142. Each actuator 144 is used to drive each transmission shaft 146 to move up-and-down for individually controlling up-and-down movement of each nozzle 142 thereto pick and place ICs. The rotational structure 16 is used to drive the transmission shaft 146 to rotate for rotating the nozzle 142.

Back referring to FIG. 1A and FIG. 1B, the rotational structures 16 of the present invention includes at least one main rotational structure 162, and at least one dependent rotational structure 164. The driving structure 18 is used to drive the transmission structure 17 for driving the main rotational structure 162 to rotate. The main rotational structure 162 can drive the dependent rotational structure 164 to rotate. The transmission structure 17 includes a first transmission unit 172 as shown in FIG. 1B, and a second transmission unit 174 as shown in FIG. 1A. The first transmission unit 172 is assembled with the driving structure 18 and the main rotational structures 162. The driving structure 18 is used to drive the first transmission unit 172 for driving the main rotational structures 162 to rotate. The second transmission unit 174 is assembled with the main rotational structure 162 and the dependent rotational structure 164. When the main rotational structure 162 is rotated by the first transmission unit 172, the second transmission unit 174 is driven by the main rotational structure 162, and the second transmission unit 174 drives the dependent rotational structure 164 to rotate. In other words, the dependent rotational structure 164 is driven by the main rotational structure 162 to rotate.

With further descriptions, the first transmission unit 172 includes a driving pulley 1722, a plurality of first main transmission pulleys 1724, and a transmission belt 1726. The driving pulley 1722 is assembled with the driving structure 18. The driving structure 18 drives the driving pulley 1722 to rotate. As shown in FIG. 1B and FIG. 3, the first main transmission pulley 1724 is assembled with the lower of the main rotational structure 162. The transmission belt 1726 is assembled with the driving pulley 1722 and the first main transmission pulley 1724. Therefore, when the driving structure 18 drives the driving pulley 1722 to rotate, the driving pulley 1722 will drive the transmission belt 1726 to rotate for driving the first main transmission pulley 1724 to rotate. One embodiment for the above mentioned driving pulley 1722 and the first main transmission pulley 1724 are belt pulleys. One embodiment for the transmission belt 1726 is a leather belt.

The second transmission unit 174 includes a second main transmission pulley 1742, a dependent transmission pulley 1744, and a transmission belt 1746. As shown in FIG. 1A and FIG. 3, the second main transmission pulley 1742 is assembled with the top of the main rotational structure 162. The dependent transmission pulley 1744, as shown in FIG. 1A and FIG. 2 is assembled with the top of the dependent rotational structure 164. The transmission belt 1746 is assembled with the second main transmission pulley 1742 and the dependent transmission pulley 1744. Therefore, when the driving structure 18 drives the main rotational structure 162 to rotate, the second main transmission pulley 1742 of the main rotational structure 162 will rotate. The second main transmission pulley 1742 will drive the transmission belt 1746 to rotate for driving the dependent transmission pulley 1744 of the dependent rotational structure 164 to rotate. Therefore, the dependent rotational structure 164 is driven by the main rotational structure 162 to rotate.

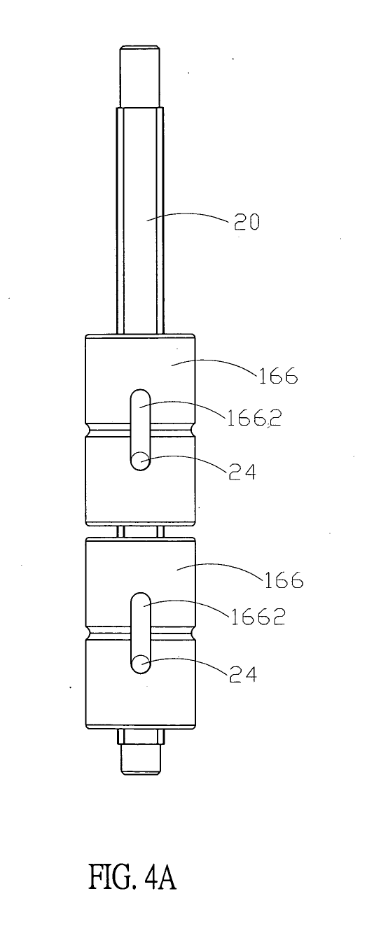

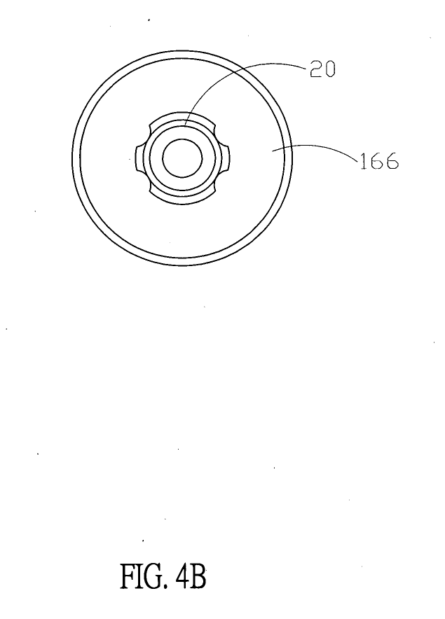

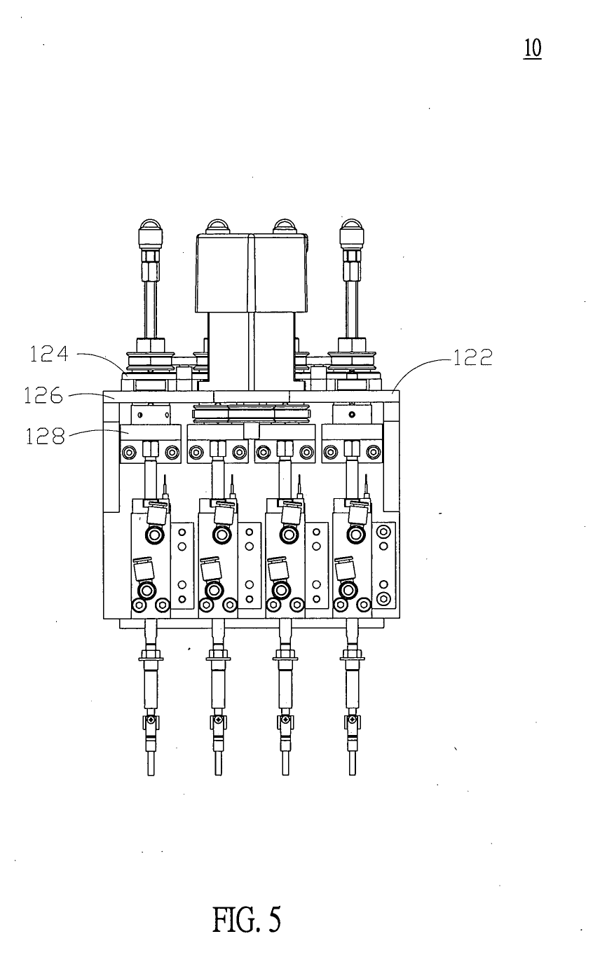

Referring to FIG. 3, FIG. 4A and FIG. 4B, the figures include a schematic view showing the rotational structure 16, a front view showing a linear sleeve 166 assembled with the hollow shaft 20, and a top view showing the linear sleeve 166 assembled with the hollow shaft 20, according to one embodiment of the present invention. As shown in the figures, each rotational structure 16 of the present invention includes at least one linear sleeve 166 and a plurality of rotational bearings. The rotational bearings at least include a first rotational bearing 1682, and a second rotational bearing 1684. The rotational bearings 168 can further include a third rotational bearing 1686 for securing firmness. Each rotational bearing individually includes an outer ring and an inner ring; and the inner ring can be rotated. The linear sleeve 166 is assembled with the hollow shaft 20. The rotational bearings 1682, 1684, and 1686 individually are mounted on the base 12 by a plurality of bearing bases 124, 126, and 128, as shown in FIG. 5. The rotational bearings 1682, 1684, and 1686 are individually assembled with the linear sleeve (166).

One embodiment for the linear sleeve 166 is a splined sleeve. As shown in FIG. 4B, the outer shape of the hollow shaft 20 is cooperated with the inner shape of the liner sleeve 166. The linear sleeve 166 is assembled with the hollow shaft 20. When the linear sleeve 166 is rotating, the linear sleeve 166 will drive the hollow shaft 20 to rotate, and further drive the transmission shaft 146 which is connected with the hollow shaft 20 to rotate, as shown in FIG. 2. Therefore, the nozzle 142, which is connected with the transmission shaft 146 will be driven to rotate.

Back referring to FIG. 4A, the figure shows that one side of the liner sleeve 166 has at least one slot 1662. One end of bar 24 is assembled with the slot 1662. The shape of the slot 1662 is not necessarily to be rectangular, so, the figure is only one embodiment of the present invention. The other end of the bar 24 is assembled with one side wall of the second main transmission pulley 1742 or/and the first main transmission pulley 1724, as shown in FIG. 3. In other words; the bar 24 is assembled with the transmission structure 17 and the linear sleeve 166 of the rotational structure 16. Therefore, the linear sleeve 166 of the main rotational structure 162 is fixed to the second main transmission pulley 1742 or/and the first main transmission pulley 1724 of the transmission structure 17. Therefore, when the first main transmission pulley 1724 is rotated, the linear sleeve 166 of the main rotational structure 162 is also driven to rotate, and the hollow shaft 20 of the main rotational structure 162 is further driven to rotate. Besides, the nozzle 142 which is connected with above mentioned hollow shaft 20 and the second main transmission pulley 1742 of the main rotational structure 162 are also driven.

The linear sleeve 166 of the dependent rotational structure 164 is fixed to the side wall of the dependent transmission pulley 1744 of the transmission structure 17 by the bar 24. The dependent transmission pulley 1744 drives the linear sleeve 166 of the dependent rotational structure 164 to rotate. Therefore, when the dependent transmission pulley 1744 is rotated by the second main transmission pulley 1742 and the transmission belt 1746 of the main rotational structure 162, the hollow shaft 20 which is passed through the linear sleeve 166 of the dependent rotational structure 164 and the nozzle 142 will be driven to rotate.

Besides, the present invention further includes at least one spacer ring 169 as shown in FIG. 3. The spacer ring 169 is mounted on the linear sleeve 166 and positioned in between the second main transmission pulley 1742 and the first main transmission pulley 1724. The spacer ring 169 is used to separate the second main transmission pulley 1742 and the first rotational bearing 1682 as well as to separate the first main transmission pulley 1724 and the second rotational bearing 1684, in order to avoid the friction resulting from the first rotational bearing 1682 and the second main transmission pulley 1742, and the second rotational bearing 1684 and the first main transmission pulley 1724. The spacer ring 169 is mounted on the linear sleeve 166 and assembled with the inner rings of the rotational bearings 1682 and 1684. In other words, the rotational bearings 1682 and 1684 are assembled with the linear sleeve 166 through spacer ring 169. When the linear sleeve 166 is rotated, the inner rings of the rotational bearings 1682 and 1684 are driven by the spacer rings 169 to rotate. Besides, when the rotational structure 16 further includes the third rotational bearing 1686, it has additional spacer ring 169 as the inner ring of the third rotational bearing 1686 for avoiding the friction between the first main transmission pulley 1724 and the third rotational bearing 1686.

Referring to FIG. 5, it is a front view showing the pick-and-place device for ICs according to one embodiment of the present invention. As shown in the figure, the present invention includes bearing bases, and the bearing bases include the first bearing base 124 and the second bearing base 126. The bearing bases further include the third bearing base 128. The bearing bases are individually mounted on the base board 122 of the base 12. The outer rings of the first rotational bearings 1682, the second rotational bearing 1684 and the third rotational bearing 1686 in the rotational structure 16 as shown in FIG. 3 are individually mounted on the first bearing base 124, the second bearing base 126 and the third bearing base 128. The second bearing base 126 is positioned on the lower of the first bearing base 124. The third bearing base 128 is positioned on the lower of the second bearing base 126. The second rotational bearing 1684 can be embedded in the base board 122, so, the base board 122 can be used as the second bearing base 126.

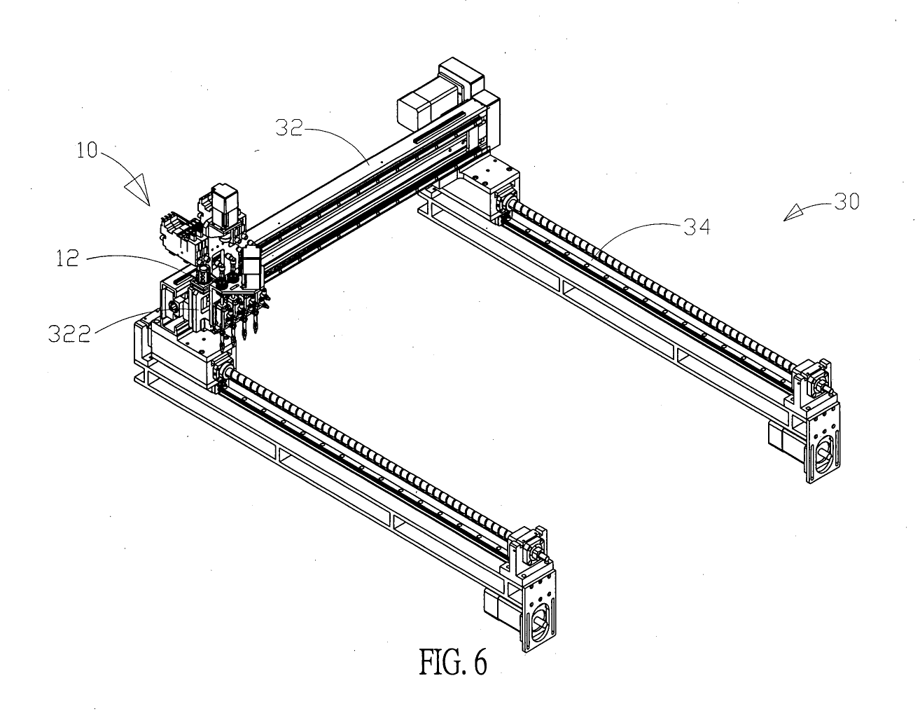

Referring to FIG. 6, it is a 3D view showing the pick-and-place device for ICs assembled with a movable device according to one embodiment of the present invention. As shown in the figure, the present invention further includes a movable device 30. The movable device 30 includes a horizontal movable structure 32 and a vertical movable structure 34. The base 12 of the pick-and-place device 10 is assembled with a movable base 322 of the movable device 30. The movable base 322 is assembled with the horizontal movable structure 32. The horizontal movable structure 32 can drive the movable base 322 to move in a horizontal direction. In other words, the pick-and-place device 10 is assembled with the horizontal movable structure 32, and the horizontal movable structure 32 can drive the pick-and-place device 10 to move in a horizontal direction. The horizontal movable structure 32 is assembled with the vertical movable structure 34. The vertical movable structure 34 drives the horizontal movable structure 32 to move in a vertical direction. Therefore, by using the horizontal movable structure 32 and the vertical movable structure 34 of the movable device 30, it can make the pick-and-place device 10 move in the horizontal and the vertical direction thereto enhance the convenience and the efficiency of picking or placing ICs.

According to above descriptions, the pick-and-place device for ICs according to the present invention comprises the pick-and-place structures, the rotational structures, the transmission structure and the driving structure. The present invention uses the driving structure to drive the transmission structure for driving the rotational structures to rotate. So, the rotational structures can also drive the nozzles to rotate. In sum, the pick-and-place device of the present invention only requires a single driving structure for driving the nozzles to rotate simultaneously. When the nozzles pick and place a plurality of ICs, the nozzles also rotate the ICs to the correct direction. So, it can enhance the convenience of picking-and-placing ICs.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A pick-and-place device for ICs comprising:
a base;
a plurality of pick-and-place structures, mounted on the base, the pick-and-place structures individually having a nozzle, the pick-and-place structures individually driving the nozzles to move up-and-down;
a plurality of rotational structures, mounted on the base and driving the nozzles to rotate;
a transmission structure, assembled with the rotational structures and driving the rotational structures to rotate; and
a driving structure, mounted on the base, the driving structure driving the transmission structure for driving the rotational structures to rotate, and the rotational structures driving the nozzles to rotate.

2. The pick-and-place device for ICs as claimed in claim 1, further comprising a plurality of hollow shafts, the hollow shafts individually passed through the rotational structures and connected with the nozzles.

3. The pick-and-place device for ICs as claimed in claim 2, further comprising a plurality of connecting ports, the connecting ports individually connected with the hollow shafts.

4. The pick-and-place device for ICs as claimed in claim 2, wherein each of the rotational structures comprises:
at least one linear sleeve, assembled with the hollow shaft; and
a plurality of rotational bearings, mounted on the base and assembled with the linear sleeve.

5. The pick-and-place device for ICs as claimed in claim 4, wherein the outer shape of the hollow shaft is cooperated with the inner shape of the liner sleeve.

6. The pick-and-place device for ICs as claimed in claim 5, wherein one side of the linear sleeve has at least one slot, at least one end of at least one bar is assembled with the slot, and the other end of the bar is assembled with the transmission structure.

7. The pick-and-place device for ICs as claimed in claim 4, wherein the linear sleeve is a splined sleeve.

8. The pick-and-place device for ICs as claimed in claim 4, further comprising at least one spacer ring, the spacer ring mounted on the linear sleeve and individually assembled with inner rings of the rotational bearings.

9. The pick-and-place device for ICs as claimed in claim 4, wherein the base comprises:
a base board; and
a plurality of bearing bases, mounted on the base board, the rotational bearings mounted on the bearing bases.

10. The pick-and-place device for ICs as claimed in claim 9, wherein the rotational bearings comprise:
a first rotational bearing, mounted on a first bearing base of the bearing bases;
a second rotational bearing, mounted on a second bearing base of the bearing bases, and positioned on the lower of the first rotational bearing; and
a third rotational bearing, mounted on a third bearing base of the bearing bases, and positioned on the lower of the second rotational bearing.

11. The pick-and-place device for ICs as claimed in claim 1, wherein the rotational structures comprise at least one main rotational structure and at least one dependant rotational structure, the driving structure drives the transmission structure for driving the main rotational structure to rotate, and the main rotational structure drives the dependent rotational structure to rotate.

12. The pick-and-place device for ICs as claimed in claim 11, wherein the transmission structure comprises:
a first transmission unit, assembled with the driving structure and the main rotational structure, the driving structure driving the first transmission unit for driving the main rotational structure to rotate; and
a second transmission unit, assembled with the main rotational structure and the dependent rotational structure, the main rotational structure rotating and further driving the second transmission unit for driving the dependant rotational structure to rotate.

13. The pick-and-place device for ICs as claimed in claim 12, wherein the first transmission unit comprises:
a driving pulley, assembled with the driving structure, the driving structure driving the driving pulley to rotate;
at least one first main transmission pulley, assembled with the main rotational structure; and
a transmission belt, assembled with the driving pulley and the first main transmission pulley, the driving pulley driving the transmission belt to rotate for driving the first main transmission pulley to rotate for driving the main rotational structure to rotate.

14. The pick-and-place device for ICs as claimed in claim 12, wherein the second transmission unit comprises:
a second main transmission pulley, assembled with the main rotational structure;
a dependent transmission pulley, assembled with the dependent rotational structure; and
a transmission belt, assembled with the second main transmission pulley and the dependent transmission pulley, the main rotational structure driving the second main transmission pulley during rotation, and the second main transmission pulley further driving the transmission belt to rotate for rotating the dependent rotational structure.

15. The pick-and-place device for ICs as claimed in claim 1, wherein each of the pick-and-place structure comprises:
an actuator, mounted on the base; and
a transmission shaft, passed through the actuator and connected with the nozzle, the rotational structure driving the transmission shaft to rotate, the actuator driving the transmission shaft to move up-and-down.

16. The pick-and-place device for ICs as claimed in claim 15, wherein the transmission shaft is connected with a hollow shaft, the transmission shaft is interlinked to the hollow shaft, and the hollow shaft is passed through the rotational structure.

17. The pick-and-place device for ICs as claimed in claim 15, wherein the actuator is a pneumatic cylinder.

18. The pick-and-place device for ICs as claimed in claim 15, wherein the transmission shaft is a hollow shaft.

19. The pick-and-place device for ICs as claimed in claim 1, further comprising a moveable device, the base assembled with the moveable device.

20. The pick-and-place device for ICs as claimed in claim 19, wherein the moveable device comprises:
a horizontal moveable structure, the base assembled with the horizontal moveable structure; and
a vertical moveable structure, the horizontal moveable structure assembled with the vertical moveable structure.

21. The pick-and-place device for ICs as claimed in claim 1, wherein the driving structure is a positioning motor.
